(19) United States
(12) Patent Application Publication
(10) Pub. No.: US 2018/0190896 A1
(43) Pub. Date: Jul. 5, 2018

(54) Ultrasonic Transmitter and Receiver

(71) Applicant: TE Connectivity Corporation, Berwyn, PA (US)

(72) Inventors: Yiliang Wu, San Ramon, CA (US); Barry C. Mathews, Fremont, CA (US); Miguel A. Morales, Fremont, CA (US); Leonard H. Radzilowski, Palo Alto, CA (US); Michael A. Oar, San Francisco, CA (US); Chaitrali Gothe, Fremont, CA (US)

(73) Assignee: TE Connectivity Corporation, Berwyn, PA (US)

(21) Appl. No.: 15/398,100

(22) Filed: Jan. 4, 2017

(51) Int. Cl. H01L 41/113; H01L 41/09; H01L 41/047; H01L 41/187; H01L 41/193; B06B 1/10; B06B 1/06

(52) U.S. Cl. CPC H01L 41/1132; H01L 41/09; H01L 41/0471; H01L 41/0477; G06K 9/0002; H01L 41/193; B06B 1/10; B06B 1/0644; H01L 41/1876

(57) ABSTRACT

An ultrasonic transmitter and ultrasonic receiver include a piezoelectric layer and at least one conductive layer comprising metal nanoparticles. The metal nanoparticles may be a silver nanoparticle, copper nanoparticle, gold nanoparticle, palladium nanoparticle, nickel nanoparticle, and the mixture thereof. Use of metal nanoparticles as a conductive layer provides for ultrasonic transmitters or receivers with smooth, dense, and highly conductive electrodes, thus resulting in reduced ultrasonic energy loss and improved image quality.

### BACKGROUND

### I. Field

The present invention relates generally to acoustic devices. More, specifically, the present invention relates to ultrasonic transmitters and receivers containing a conductive layer printed with nanoparticle inks.

### II. Background Details

Acoustic devices such as ultrasonic transmitters and receivers have a broad range of applications, such as in medical imaging, fingerprint scanners, etc. Ultrasonic transmitters and receivers include a conductive layer which is often prepared with sputtered metal or printed with polymer thick film (PTF) conductive pastes. Although a sputtered metal conductive layer has a low surface roughness, sputtering is a slow and high-cost process. It involves the use of a vacuum and is not compatible with roll-to-roll manufacturing. Sputtering a conductive layer of a few microns (i.e. μm) to about 10 microns in thickness is time-consuming. Printing PTF conductive pastes is an additive and low-cost process. It can be made in a roll-to-roll manner. However, PTF conductive layers can exhibit large surface roughness and nano-sized to micron-sized voids, which can translate into poor electrical performance and poor image quality due to ultrasonic wave energy loss at the roughness interface or the interfaces between the conductive materials and the voids. While progress has been made in providing improved ultrasonic transmitters and receivers with PTF conductive pastes, there remains a need for improved acoustic devices having a dense and smooth conductive layer.

### SUMMARY

An ultrasonic transmitter includes a piezoelectric layer, a first conductive layer which is above the piezoelectric layer, and a second conductive layer which is below the piezoelectric layer. At least one of the first and the second conductive layers comprises metal nanoparticles. The metal nanoparticles may be a silver nanoparticle, copper nanoparticle, gold nanoparticle, palladium nanoparticle, nickel nanoparticle, and the mixture thereof.

An ultrasonic receiver includes a piezoelectric layer, and a conductive layer which is on one side of the piezoelectric layer, and a thin-film transistor (TFT) array which is on the other side of the piezoelectric layer. The conductive layer comprises metal nanoparticles, which may be a silver nanoparticle, copper nanoparticle, gold nanoparticle, palladium nanoparticle, nickel nanoparticle, and the mixture thereof.

Use of metal nanoparticles as a conductive layer provides for ultrasonic transmitters or receivers with smooth, dense, and highly conductive electrodes, thus resulting in reduced ultrasonic energy loss and better image quality.

### BRIEF DESCRIPTION OF THE DRAWINGS

FIG. 1 is an example of the structure of an ultrasonic transmitter.

FIG. 2 is an example of the structure of an ultrasonic receiver.

FIG. 3 shows a cross-section of an ultrasonic device that includes a conductive layer made from silver nanoparticle ink.

FIG. 4 shows a cross-section of an ultrasonic device that includes a conductive layer made from a polymer thick film silver paste.

FIG. 5 is the top view of the receiver shown in FIG. 2.

FIG. 6 shows elements of an exemplary ultrasonic fingerprint image sensor.

FIG. 7 illustrates metal nanoparticle ink conductive layer screen printed on a PVDF substrate.

FIG. 8 illustrates a pair of graphs for comparing the surface roughness of silver nanoparticle conductive layer to that of a polymer thick film conductive layer using white light interferometry.

### DETAILED DESCRIPTION

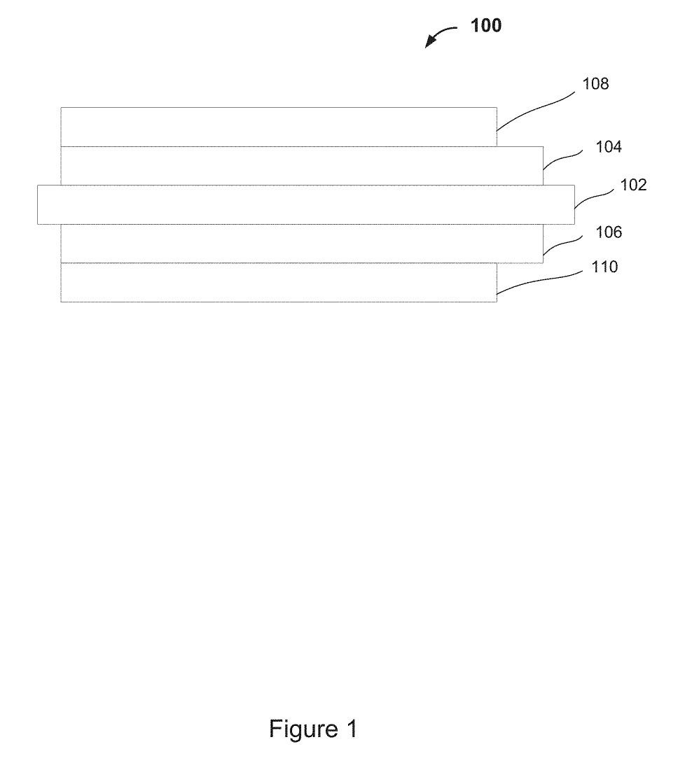

FIG. 1 is an example of the structure of an ultrasonic transmitter 100. The transmitter 100 may include a piezoelectric layer 102, an upper conductive layer 104 in contact with and above an upper surface of the piezoelectric layer 102, and a lower conductive layer 106 in contact with and below a lower surface of the piezoelectric layer 102. The transmitter 100 may further include an upper overcoat/protection layer 108 in contact with and above an upper surface of the upper conductive layer 104 and a lower overcoat/protection layer 110 in contact with and below a lower surface of the lower conductive layer 106. Herein, the upper conductive layer and the upper overcoat layer may be referred to as the first conductive layer and the first overcoat layer; the lower conductive layer and the lower overcoat layer may be referred to as the second conductive layer and the second overcoat layer.

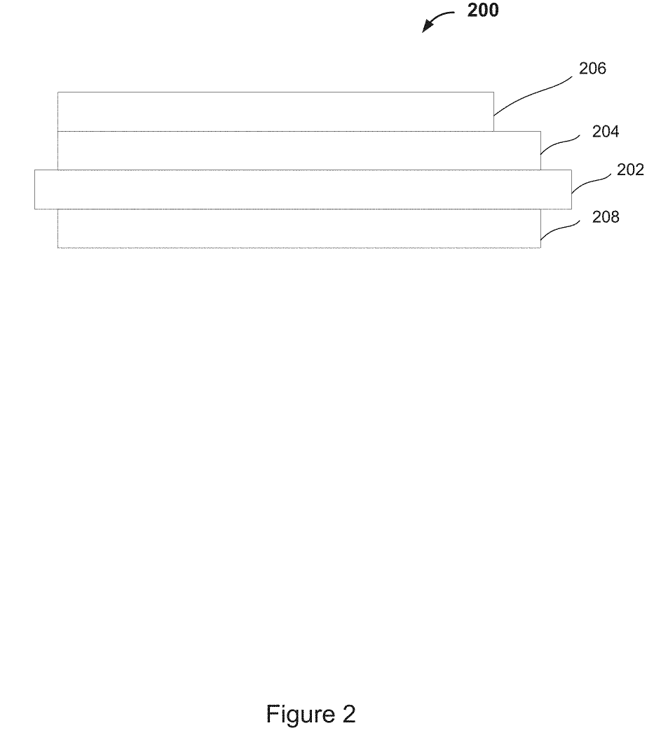

FIG. 2 is an example of the structure of an ultrasonic receiver 200. The receiver 200 may include a piezoelectric layer 202, an upper conductive layer 204 in contact with and above an upper surface of the piezoelectric layer 202, and an upper overcoat/protection layer 206 in contact with and above an upper surface of the upper conductive layer 204. The receiver 200 may further include a thin-film transistor (TFT) array 208 in contact with and below a lower surface of the piezoelectric film 202.

The piezoelectric film 202, conductive layer 204 and overcoat/protection layer 206 may be the same as or different from the piezoelectric layer 102, conductive layer 104 and/or 106, and overcoat/protection layer 108 described with respect to FIG. 1. The TFT array 208 may serve as an electrode below the piezoelectric layer 202. In this example, a signal received in the piezoelectric layer 202 is transferred into a digital signal, and subsequently processed into a digital image by circuit elements external to the receiver 200.

The transmitter or the receiver may have a plurality of transmitter or receiver elements described above. A transmitter adjacent to the receiver generates a transmit signal at an ultrasonic frequency. The transmit signal is reflected from a surface such as a finger to produce a reflected signal which will be detected by the receiver. The received signal can be the reflected signal itself, or the superposition of the transmit signal and the reflected signal. In general, the received signal represents the difference in acoustic impedances across the surface.

The piezoelectric layer 102 or 202 may include ceramic materials, for example, PZT (lead zirconate titanate), PST (lead strontium titanate), quartz, (Pb, Sm)TiO₃, PMN(Pb(MgNb)O₃)-PT(PbTiO₃), or other like materials. Organic piezoelectric materials such as PVDF(polyvinylidene fluoride, or polyvinylidene difluoride) or PVDF copolymer, terpolymers such as PVDF-TrFE (P(VDF-trifluoroethylene)), P(VDF-tetrafluoroethylene), poly(vinylidene fluoride-hexafluoropropylene) (P(VDF-HFP), poly(vinylidene fluoride-chlorotrifluoroethylene) (P(VDF-CTFE), poly(vinylidene fluoride-trifluoroethylene-chlorofluoroethylene) (P(VDF-TrFE-CFE)) and the like, may be used for certain applications, such as large area ultrasonic image scanners. The piezoelectric layer may have a thickness from about 5 μm to about 500 μm, including from about 5 μm to about 200 μm, and from about 10 μm to about 150 μm. In embodiments, the organic piezoelectric material is a free-standing film, having a thickness from about 15 μm to about 200 μm, including from about 20 μm to about 100 μm, specifically, the organic piezoelectric film is a PVDF film having a thickness from about 25 to about 35 μm. In some embodiments, 102 and 202 are the same piezoelectric material, for example, they both are organic piezoelectric material. In other embodiments, 102 and 202 are different materials.

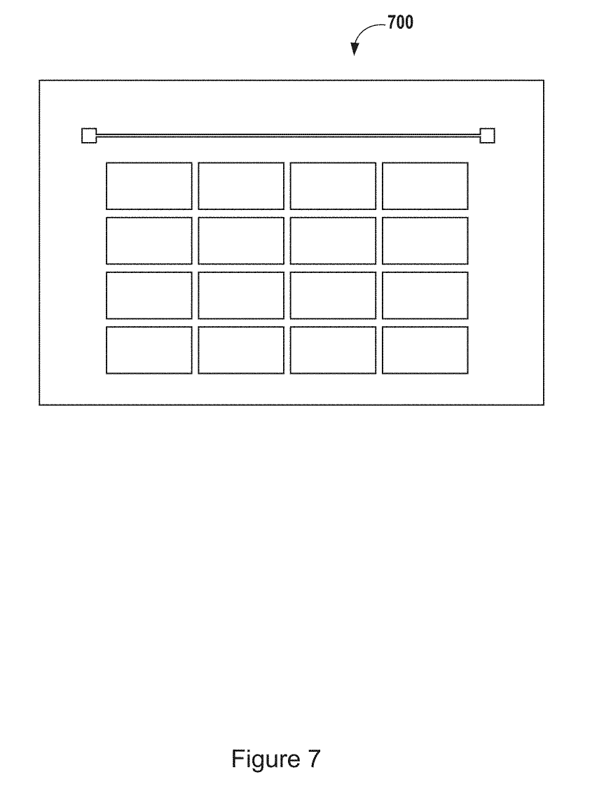

The conductive layers 104, 106, and 204 may include a metal nanoparticle ink, such as copper, silver, gold, palladium, or nickel nanoparticle, an alloy thereof, or a mixture thereof. In one example the metal nanoparticle ink may be silver nanoparticle ink. An exemplary silver nanoparticle ink may include PG-007 and or PS-004 (Paru Inc., Korea), GDP-NO ink (ANP, Korea), PSI-219 (Novacentrix, USA), and the like. The ink may comprise, for example, from about 40 wt % to about ˜85 wt % silver nanoparticles including from about 60 wt % to about 80 wt % silver nanoparticles dispersed in proper solvents, for example, diethylene glycol, ethylene glycol (EG), propylene, glycol monomethyl ether acetate, propylene glycol monomethyl ether, terpineol, 2-(2-Ethoxyethoxy)ethanol, and the like solvent. The metal nanoparticle ink may be patterned into the desired electrode structures using screen (flat bed or rotary), flexo, gravure, aerosol-jet, dispense jet, inkjet, stencil printing methods, or other additive printing techniques. Alternatively, coating methods such as spin coating, dip coating, doctor blade coating, or slot die coating may be used to deposit the metal nanoparticle ink structure. Furthermore, the conductive layers 104, 106, and 204 may be fully or incompletely sintered. In one screen printing example a screen with 280 mesh counts and an emulsion thickness of 0.015 mm (0.0006 inch) may be used, with an off contact set at 40-50 μm. FIG. 7 shows an example of metal nanoparticle ink conductive layer 700 screen printed on a PVDF substrate after allowing the ink to dry. For screen printing, the ink has a viscosity from about 200 to about 400 pascal-second (Pa-s), including from about 250 to about 350 Pa-s, at a low shear rate of 0.1 s⁻¹, and a viscosity from about 1.0 to about 10 Pa-s, including from about 1.5 to about 8 Pa-s, at a high shear rate of 200 s⁻¹. In other words, the ink has a high shear thinning index (which is the viscosity at the low shear rate over the viscosity at the high shear rate) from about 40 to about 180, including from about 50 to about 150. After high shear, the ink viscosity will recover to between about 50% to 95% of its original viscosity measured at the low shear rate of 0.1 s⁻¹ within 60 seconds after high shear, including from about 50% to about 75% or from between about 75% to 95%. In some embodiments, at least one of the first and the second conductive layers of the transmitter comprises metal nanoparticles. Preferably, the conductive layer which is closer to the receiver comprises metal nanoparticles. In other embodiments, both of the first and the second conductive layers comprise metal nanoparticles. The conductive layer of receiver may comprise the metal nanoparticles. In further embodiments, a majority of the conductive layers may contain metal nanoparticles. In other embodiments, the conductive layers may be substantially comprised of metal nanoparticles.

The silver nanoparticle ink comprises silver nanoparticles having an average particle diameter in the range from about 2 nm to about 950 nm, alternatively, from about 5 nm to about 800 nm including from about 50 nm to about 300 nm. In some embodiments, the silver nanoparticles may have a shell layer such as an organic compound physically or chemically attached to their surface to prevent the aggregation of the nanoparticles in the ink. The particle size refers to the silver metal itself, and does not include the organic shell layer. The particle size can be determined using for example Transmission Electron Microscopy (TEM) or Scanning Electron Microscopy (SEM). In some embodiments, the silver nanoparticles are at least partially stabilized with a hygroscopic or water-soluble compound. Exemplary hygroscopic compound includes polyvinylpyrrolidone (PVP), polyvinyl alcohol (PVA), polyethyleneimine, hydroxyl cellulose, polyethylene glycol (PEG), polyethylene oxide (PEO), poly(acrylic acid), and the like. Other commonly used organic compounds such as organoamine or thiol compounds can be used as well.

In some embodiments, the metal nanoparticles are completed fused together in the conductive layer. Namely, individual metal nanoparticle cannot be detected using common tools such as SEM. In other embodiments, the metal nanoparticles are not completely fused together and individual metal nanoparticle can be clearly seen using common characterization tools. In particular, the average particle diameter of the metal nanoparticles in the conductive layer after drying and annealing is substantially the same as that in the metal nanoparticle ink.

The metal nanoparticle ink provides a smooth electrode film due to the small particle size and spherical shape. Silver nanoparticle ink, for example, may have a particle size from about 10 nm to about 800 nm, such as from about 50 nm to about 800 nm, or from about 80 nm to about 300 nm. As such, a transmitter and receiver using metal nanoparticle ink electrodes benefit from reduced ultrasonic energy loss and thus provide a highly conductive electrode for ultrasonic transmitter/receiver applications.

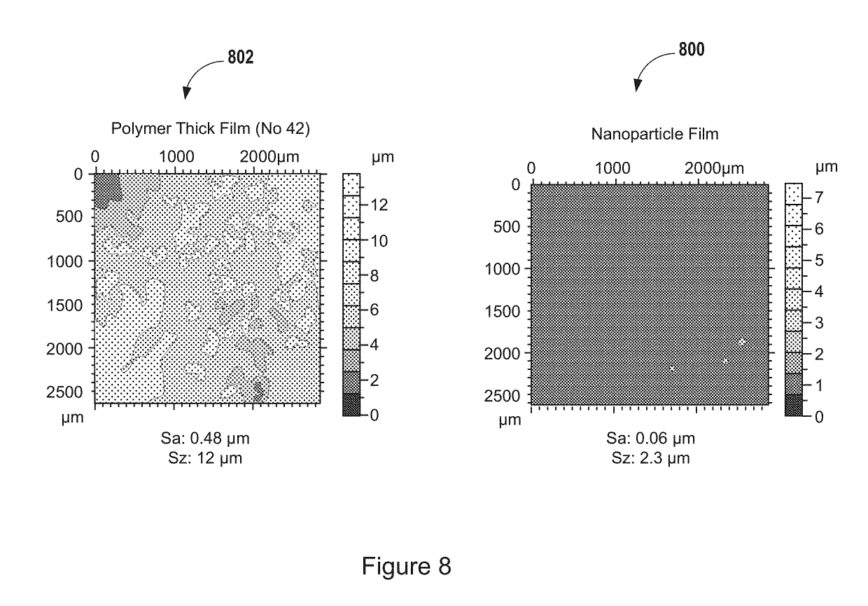

Conductive layers 104, 106, and 204 including, for example, silver nanoparticle ink, may have a thickness of about 1 to 20 μm, including 1 to 12 μm or 5 to 12 μm, and a low surface roughness. The surface roughness can be characterized using a profile surface roughness for example the parameter Ra by a surface profilometer. In some embodiments, the Ra is less than 0.4 μm, including less than 0.2 μm, or less than 0.1 μm. The surface roughness can also be characterized using areal roughness for example the parameter Sz or Sa by a white light interferometer. The conductive layer has an Sz, which is the distance from the highest peak to the lowest valley, of less than 5 μm, including less than 3 μm, or less than 2 μm, as determined by for example white light interferometry at a scan area of for example 3×3 mm². The conductive layer has an Sa, for example, less than 0.4 μm, including less than 0.2 μm, or less than 0.1 μm as determined by for example white light interferometry at a scan area of for example 3×3 mm². In this example, silver nanoparticle ink conductive layers 104, 106 and 204 may exhibit a gloss greater than about 50 gloss units (GU), including greater than about 80 GU, or greater than about 100 GU. FIG. 8 shows graphs 800 and 802 that compare the surface roughness of silver nanoparticle film to that of a polymer thick film conductor, respectively, for a 3×3 mm² scanned area. The polymer thick film shows an Sa of about 0.48 μm and an Sz of 12 μm, while the silver nanoparticle film exhibited an Sa of 0.06 μm and an Sz of about 2.3 μm.

The metal nanoparticle ink conductive layers 104, 106, and 204 may be processed and dried and/or annealed at any temperature. The preferred temperature will have no adverse effect on the piezoelectric layer or other pre-deposited component. In some embodiments, the metal nanoparticle ink is dried and annealed at a temperature no more than 200° C., including no more than 170° C., or no more than 150° C., or no more than 100° C. In specific embodiments, the metal nanoparticles are processed (dried and annealed) at a temperature of 80° C. or less when PVDF, for example, is used as the piezoelectric layer 102 or 202. Furthermore, the metal nanoparticles are processed at a temperature of 60° C. or less when PVDF, for example, is used as the piezoelectric layer 102 or 202. PVDF film having a high d₃₃ (a high content of beta-phase) is often obtained though dedicated mechanical stretching processes. Annealed and poled PVDF film has a crystal relaxation temperature of about 75° C. Therefore, processing the PVDF film above this relaxation temperature will cause reduction of the piezo-electrical properties such as the reduction of d₃₃. In addition, processing the PVDF film at a high temperature (e.g. >80° C.) also causes a large shrinkage of the film due to the crystal relaxation. When PVDF is used as the piezoelectric layer, low-temperature processing of the metal nanoparticle layer is critical. This is significantly different from other piezoelectric materials such as inorganic piezoelectric materials and PVDF-TrFE copolymers, which have a stable piezoelectric phase at a relatively higher temperature and may, therefore, be processed at a relatively higher temperature. The metal nanoparticle conductive layer, for example, has a resistivity of less than 1.0×10⁴ ohm-cm, including less than 8.0×10⁻⁵ ohm-cm and less than 5.0×10⁻⁵ ohm-cm. In specific embodiments, the conductive layer 104 and 106 in the transmitter may have a resistivity lower than 8.0×10⁻⁵ ohm-cm, lower than 5.0×10⁻⁵ ohm-cm, and even lower than 2.0×10⁻⁵ ohm-cm. The low resistivity results in minimal overall resistive losses, which are known to reduce sensitivity. The resistivity of conductive layer 204 may be the same or different from that of conductive layers 104 and 106. The metal nanoparticle conductive layer also exhibits optimal adhesion to the piezoelectric material. For example, the conductive layers 104, 106, and 204 may have an adhesion force to the piezoelectric layer 102 greater than 1.0 N/cm, including greater than 1.5 N/cm, and greater than 2.0 N/cm, as measured by the 90 degree peel method.

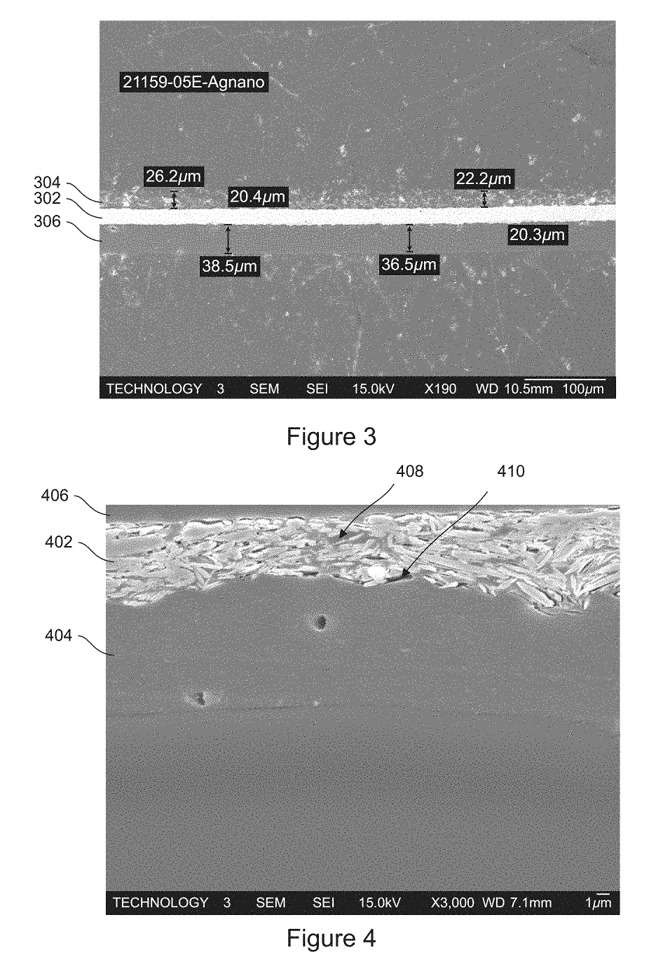

Due to the small particle size, the conductive layer made from the nanoparticle ink not only provides a smooth surface, but also exhibits a dense layer. Few, if any, voids or pinholes can be found in the conductive layer. On the other hand, due to the large particle size and the presence of polymer binders, the conductive layer prepared from the PTF paste has nano to micron sized voids/pinholes or nano to micron sized areas with polymer binder only. FIGS. 3 and 4 show examples of the cross-section of portions of an ultrasonic device that includes a conductive layer 302 made from a silver nanoparticle ink and a conductive layer 402 made from a polymer thick film silver paste, respectively. FIG. 3 also shows an overcoat layer 304 above and a PVDF layer 306 below the conductive layer 302. FIG. 4 also shows an overcoat layer 404 below and a PVDF layer 406 above the conductive layer 402. Since the polymer thick film silver paste 402 is made up of different materials, portions of the paste 402 include air voids (e.g., 408 in FIG. 4), as well as areas of the paste that are primarily just the polymer binder (represented by the dark regions, e.g., 410, in FIG. 4). Since different materials have different acoustic impedances—e.g., air voids and polymer binders have a significantly smaller acoustic impedance than silver—these voids and polymer-only areas can cause an image gradient. In some exemplary embodiments, the silver nanoparticle ink conductive layer has a high metal content, such as for example at least 90 wt %, including at least 95 wt %, or at least 97 wt %.

The overcoat/protection layers 108, 110 may include a dielectric, insulating material, such as polyacrylate, epoxy resin, polyester, styrene polymer, polyamide, polyurethane, and the like. The overcoat layer can be processed in a similar manner to the conductive layer. The overcoat layer can be either thermally cured or UV cured.

It should be noted that the current acoustic device is different from other passive electronic devices involving a piezoelectric material and a metal nanoparticle conductive layer. In the present embodiments, an ultrasonic wave will pass through the conductive layer such that the conductive layer is considered an active component of the final integrated device. The layer will absorb, reflect, and scatter the ultrasonic wave. The metal nanoparticle conductive layer in conventional passive electronic devices may provide the function of conducting current only.

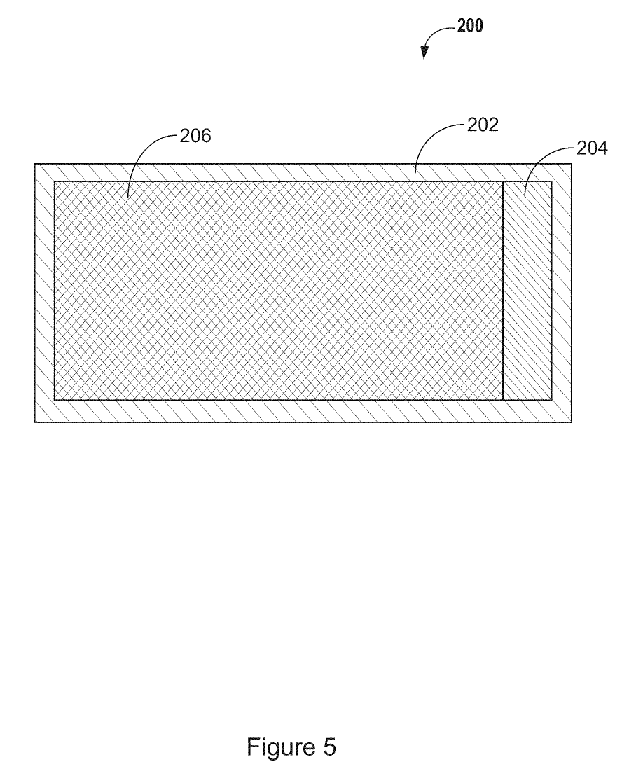

FIG. 5 is the top view of the receiver 200 shown in FIG. 2. In the example shown in FIG. 5, the piezoelectric film 202 is wider than the nanoparticle ink conductive layer 204 and the overcoat/protection layer 206. In one embodiment the conductive layer 204 and/or overcoat/protection layer 206 may have a width of approximately 6 mm, and the receiver may have a length of approximately 12 mm.

In certain embodiments, the transmitter and the receiver may include a PVDF piezoelectric layer and a metal nanoparticle conductive layer. The metal nanoparticle conductive layer may be dried and annealed at a temperature of up to about 80° C. and may have a surface roughness less than about 0.2 microns and a resistivity less than about 5.0×10⁻⁵ ohm-cm. In other embodiments, the metal nanoparticle conductive layer may be correspond to a silver nanoparticle conductive layer containing incompletely fused silver nanoparticles. The PVDF piezoelectric layer may have a beta-crystal phase more than 40 wt % or more than 50 wt % as determined by the differential scanning calorimetry method. The PVDF layer may have a d₃₃ greater than 14×10⁻¹² Coulombs/Newton (C/N), including greater than 16×10⁻¹² C/N, or greater than 17×10⁻¹² C/N.

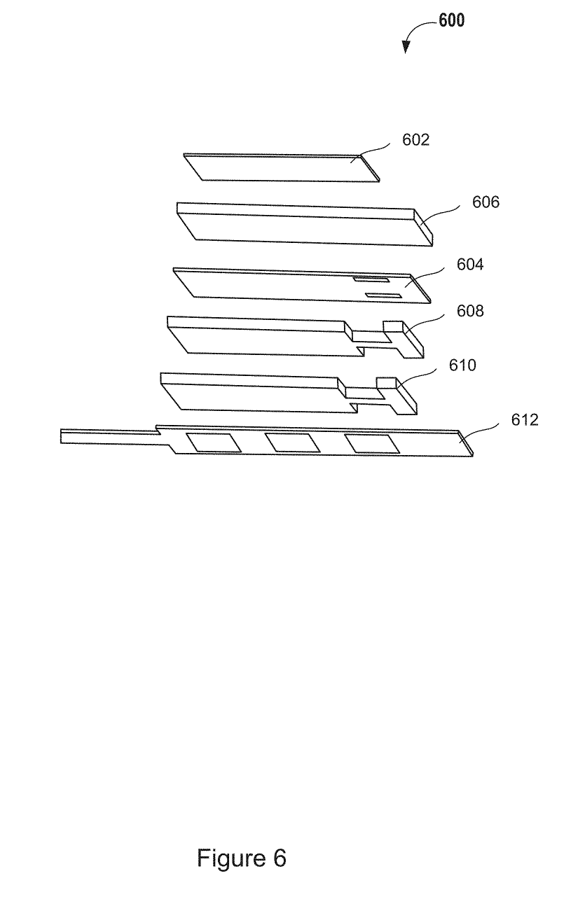

FIG. 6 shows elements of an example of an ultrasonic fingerprint image sensor 600 including a receiver 602 and a transmitter 604 as described above. Specifically the sensor 600 includes a receiver layer 602 such as the receiver 200 described above, and a transmitter layer 604, such as the transmitter 100 described above. The sensor 600 also includes a TFT array 606 between the receiver layer 602 and transmitter layer 604. The sensor 600 includes an optional acoustic isolator 608 below the transmitter layer 604, and an optional stiffener 610 below the acoustic isolator 608. The sensor 600 also includes a printed circuit board (PCB) 612 below the stiffener 610. The acoustic isolator 608 isolates the PCB 612 below transmitter layer 604 from the ultrasonic waves generated by the transmitter layer 604. The acoustic isolator 608 may be porous materials such as foams or composite materials with porous fillers. The stiffener 610 helps prevent the PCB 612 from bending or undergoing stress when a finger is pressed on top of the sensor 600. The stiffener 610 may be for example metal shims, rigid polymers such as liquid crystalline polymers, polyurethanes, polyimide, and the like. The sensor 600 may also include a platen above the receiver layer 602 against which a finger may be pressed.

When a finger is pressed on the platen, ultrasonic energy is generated and transmitted from the transmitter layer 604 up through the TFT array 606, receiver layer 602 and platen to the ridges of the finger. This ultrasonic energy is absorbed by the ridges and reflected by the valleys of the finger. The reflected energy is detected by the receiver layer 602 attached to the TFT array. The TFT array converts the received, reflected energy to a digital signal. External circuitry may translate that digital signal into a fingerprint image.

While various embodiments of the invention have been described, it will be apparent to those of ordinary skill in the art that many more embodiments and implementations are possible within the scope of the invention. Accordingly, the invention is not to be restricted except in light of the attached claims and their equivalents.

We claim:

1. An ultrasonic transmitter comprising:
a piezoelectric layer;
a first conductive layer which is above the piezoelectric layer; and
a second conductive layer which is below the piezoelectric layer; and
wherein at least one of the first and the second conductive layers comprises metal nanoparticles.

2. The ultrasonic transmitter of claim 1, further comprising:
a first overcoat layer which is above the first conductive layer; and
a second overcoat layer which is below the second conductive layer.

3. The ultrasonic transmitter of claim 1, wherein the first, the second, or the first and the second conductive layers comprise silver metal nanoparticles.

4. The ultrasonic transmitter of claim 1, wherein the first conductive layer is closer to an ultrasonic receiver, and the first conductive layer comprises metal nanoparticles.

5. The ultrasonic transmitter of claim 1, wherein the metal nanoparticle is selected from the group consisting of silver nanoparticle, copper nanoparticle, gold nanoparticle, palladium nanoparticle, nickel nanoparticle, and the mixture thereof.

6. The ultrasonic transmitter of claim 1, wherein the conductive layers have a thickness from about 1 to about 12 μm, and the conductive layers have a surface roughness (Ra) less than 0.4 μm.

7. The ultrasonic transmitter of claim 1, wherein the conductive layers have a thickness from about 5 to about 12 μm, and the conductive layers have a surface roughness (Ra) less than 0.2 μm.

8. The ultrasonic transmitter of claim 1, wherein at least one of the first and second conductive layers has a gloss greater than 50 GU.

9. The ultrasonic transmitter of claim 1, wherein at least one of the conductive layers has a resistivity less than 8.0×10⁻⁵ ohm-cm.

10. The ultrasonic transmitter of claim 1, where in the piezoelectric layer comprises one or more of PZT, PST, quartz, (Pb, Sm)TiO₃, PMN(PB(MgNb)O₃)-PT(PbTiO₃), PVDF, PVDF-TrFE, P(VDF-tetrafluoroethylene), poly(vinylidene fluoride-hexafluoropropylene) (P(VDF-HFP), poly(vinylidene fluoride-chlorotrifluoroethylene) (P(VDF-CTFE), and poly(vinylidene fluoride-trifluoroethylene-chlorofluoroethylene) (P(VDF-TrFE-CFE)).

11. The ultrasonic transmitter of claim 1, wherein at least one of the conductive layers has a 90 degree peel adhesion force to the piezoelectric layer greater than 1.0 N/cm.

12. The ultrasonic transmitter of claim 1, wherein at least one of the conductive layers comprises metal nanoparticles which are incompletely sintered.

13. An ultrasonic receiver comprising:
a piezoelectric layer;
a conductive layer which is on one side of the piezoelectric layer, wherein the conductive layer comprises metal nanoparticles; and
a thin film transistor array which is on the other side of the piezoelectric layer.

14. The ultrasonic receiver of claim 13, wherein the conductive layer comprises silver metal nanoparticles.

15. The ultrasonic receiver of claim 13, wherein the metal nanoparticle is selected from the group consisting of silver nanoparticle, copper nanoparticle, gold nanoparticle, palladium nanoparticle, nickel nanoparticle, and the mixture thereof.

16. The ultrasonic receiver of claim 13, wherein the conductive layer has a thickness from about 5 to about 12 μm, and the conductive layer has a surface roughness (Ra) less than 0.2 μm.

17. The ultrasonic receiver of claim 13, wherein the conductive layer has a gloss greater than 50 GU.

18. The ultrasonic receiver of claim 13, wherein the conductive layer has a resistivity less than 8.0×10⁻⁵ ohms cm.

19. The ultrasonic receiver of claim 13, where in the piezoelectric layer comprises one or more of PZT, PST, quartz, (Pb, Sm)TiO₃, PMN(PB(MgNb)O₃)-PT(PbTiO₃), PVDF, PVDF-TrFE, P(VDF-tetrafluoroethylene), poly(vinylidene fluoride-hexafluoropropylene) (P(VDF-HFP), poly(vinylidene fluoride-chlorotrifluoroethylene) (P(VDF-CTFE), and poly(vinylidene fluoride-trifluoroethylene-chlorofluoroethylene) (P(VDF-TrFE-CFE)).

20. The ultrasonic receiver of claim 13, wherein the conductive layer has a 90 degree peel adhesion force to the piezoelectric layer greater than 1.0 N/cm.

21. The ultrasonic receiver of claim 13, wherein the conductive layer comprises metal nanoparticles which are incompletely sintered.

22. An ultrasonic device (transmitter or receiver) comprising:
a PVDF film; and
a metal nanoparticle conductive layer, wherein the metal nanoparticle conductive layer is dried and annealed at a temperature no more than 80° C. and has a surface roughness less than 0.2 μm and a resistivity less than 5.0×10⁻⁵ ohm-cm.
